(19) United States
(12) Patent Application Publication
(10) Pub. No.: US 2025/0046755 A1
(43) Pub. Date: Feb. 6, 2025

(54) SEMICONDUCTOR PACKAGE

(71) Applicant: SAMSUNG ELECTRONICS CO., LTD., Suwon-si (KR)

(72) Inventors: Myungsam KANG, Suwon-si (KR); Chilwoo KWON, Suwon-si (KR); Okgyeong PARK, Suwon-si (KR)

(21) Appl. No.: 18/740,075

(22) Filed: Jun. 11, 2024

(30) Foreign Application Priority Data
Jul. 31, 2023 (KR) 10-2023-0099831

(51) Int. Cl. H01L 25/065; H01L 23/00; H01L 23/13; H01L 23/31; H01L 23/498; H01L 23/538; H01L 23/64; H10B 80/00

(52) U.S. Cl. CPC H01L 25/0655; H01L 23/13; H01L 23/3178; H01L 23/49822; H01L 23/5384; H01L 23/5386; H01L 23/642; H01L 24/16; H01L 28/65; H10B 80/00; H01L 2224/16227; H01L 2224/16238; H01L 2924/1431; H01L 2924/1436

(57) ABSTRACT

A semiconductor package includes a ceramic substrate having a cavity, a lower redistribution structure on a lower surface of the ceramic substrate and electrically connected to the ceramic substrate, an upper redistribution structure on an upper surface of the ceramic substrate and electrically connected to the ceramic substrate, a plurality of semiconductor chips arranged in a first direction on the upper redistribution structure, and a bridge chip structure in the cavity of the ceramic substrate and including a bridge chip electrically connecting the plurality of semiconductor chips to each other.

### CROSS-REFERENCE TO RELATED APPLICATION

This application is based on and claims priority under 35 U.S.C. § 119 to Korean Patent Application No. 10-2023-0099831, filed on Jul. 31, 2023, in the Korean Intellectual Property Office, the disclosure of which is incorporated by reference herein in its entirety.

### BACKGROUND

The inventive concept relates to a semiconductor package, and more particularly, to a semiconductor package including a bridge chip.

Recently, in the electronics product market, demand for portable devices is rapidly increasing, and as a result, there is a continuous demand for miniaturization and weight reduction of electronic components mounted on these electronic products. In order to miniaturize and lighten electronic components, semiconductor packages mounted on the electronic components are required to process high amounts of data while becoming smaller in volume. Accordingly, research and development on semiconductor packages including bridge chips are continuously being conducted in order to realize high performance and large capacity along with the miniaturization and weight reduction.

### SUMMARY

The inventive concept provides a semiconductor package including a ceramic substrate including a cavity and a bridge chip within the cavity.

The problem to be solved by the technical idea of the inventive concept is not limited to the problem to be solved by inventive concept mentioned above, and other problems not mentioned are clearly understood by those skilled in the art from the description below.

According to an aspect of the inventive concept, there is provided a semiconductor package including a ceramic substrate having a cavity, a lower redistribution structure on a lower surface of the ceramic substrate and electrically connected to the ceramic substrate, an upper redistribution structure on an upper surface of the ceramic substrate and electrically connected to the ceramic substrate, a plurality of semiconductor chips arranged in a first (e.g., horizontal) direction on the upper redistribution structure, and a bridge chip structure in the cavity of the ceramic substrate and including a bridge chip electrically connecting the plurality of semiconductor chips to each other.

Also, according to another aspect of the inventive concept, there is provided a semiconductor package including a ceramic substrate having a cavity, the ceramic substrate including a plurality of first insulating layers and a first circuit wiring layer between the plurality of first insulating layers, a lower redistribution structure on a lower surface of the ceramic substrate, the lower redistribution structure including a plurality of second insulating layers and a second circuit wiring layer between the plurality of second insulating layers and electrically connected to the first circuit wiring layer, an upper redistribution structure on an upper surface of the ceramic substrate, the upper redistribution structure including a plurality of third insulating layers and a third circuit wiring layer between the plurality of third insulating layers and electrically connected to the first circuit wiring layer, a plurality of semiconductor chips arranged in a first (e.g., a horizontal) direction on the upper redistribution structure, a bridge chip structure in the cavity of the ceramic substrate and including a bridge chip electrically connecting the plurality of semiconductor chips to each other, and an encapsulation layer encapsulating the bridge chip structure within the cavity, wherein the encapsulation layer includes ceramic material, resin, or a combination thereof.

Also, according to another aspect of the inventive concept, there is provided a semiconductor package including a ceramic substrate having a cavity, a plurality of first insulating layers, and a first circuit wiring layer between the plurality of first insulating layers, a lower redistribution structure on a lower surface of the ceramic substrate, the lower redistribution structure including a plurality of second insulating layers and a second circuit wiring layer between the plurality of second insulating layers and electrically connected to the first circuit wiring layer, an upper redistribution structure on an upper surface of the ceramic substrate, the upper redistribution structure including a plurality of third insulating layers and a third circuit wiring layer between the plurality of third insulating layers and electrically connected to the first circuit wiring layer, a plurality of semiconductor chips arranged in a first (e.g., a horizontal) direction on the upper redistribution structure and including a logic semiconductor chip or a high bandwidth memory (HBM) semiconductor chip, a bridge chip structure in the cavity of the ceramic substrate and including a bridge chip electrically connecting the plurality of semiconductor chips to each other, an encapsulation layer encapsulating the bridge chip structure within the cavity, wherein the encapsulation layer includes ceramic material, resin, or a combination thereof, and a capacitor structure at an interface between the ceramic substrate and the upper redistribution structure, the capacitor structure including a lower electrode layer on the upper surface of the ceramic substrate, a dielectric layer on the upper surface of the lower electrode layer, and an upper electrode layer on an upper surface of the dielectric layer.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view schematically showing a semiconductor package according to an embodiment;

FIG. 2 is an enlarged cross-sectional view of portion EX1 of FIG. 1;

FIG. 3 is a cross-sectional view schematically showing a semiconductor package according to an embodiment;

FIG. 4 is an enlarged cross-sectional view of portion EX2 of FIG. 3;

FIGS. 5 to 11 are cross-sectional views schematically showing a method of manufacturing a semiconductor package, according to an embodiment;

FIG. 12 is a cross-sectional view schematically showing a semiconductor package according to an embodiment;

FIG. 13 is an enlarged cross-sectional view of portion EX3 of FIG. 12; and

FIGS. 14 and 15 are cross-sectional views schematically showing a method of manufacturing a semiconductor package, according to an embodiment.

### DETAILED DESCRIPTION OF THE EMBODIMENTS

Hereinafter, embodiments of the technical idea of the inventive concept are described in detail with reference to the attached drawings. The same reference numerals are used for the same components in the drawings, and the descriptions already given for them are omitted.

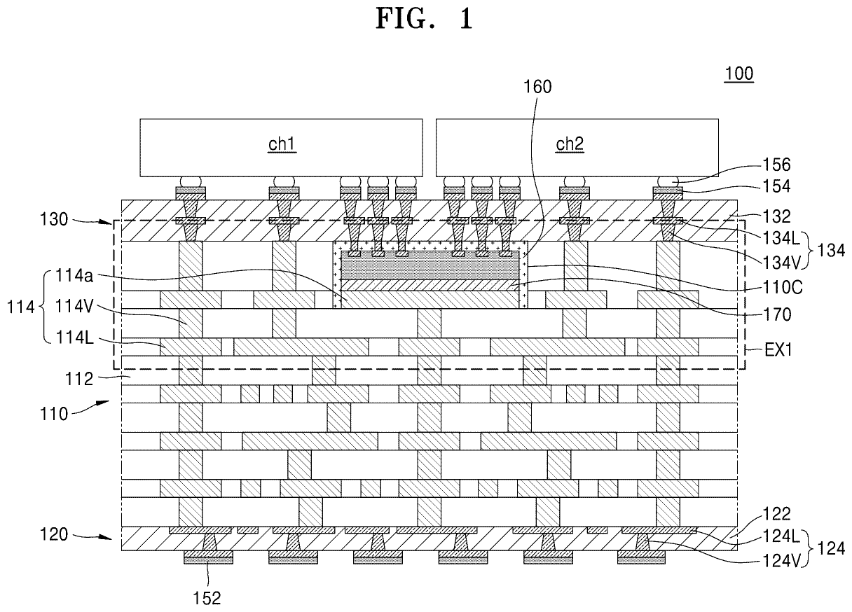

FIG. 1 is a cross-sectional view schematically showing a semiconductor package according to an embodiment.

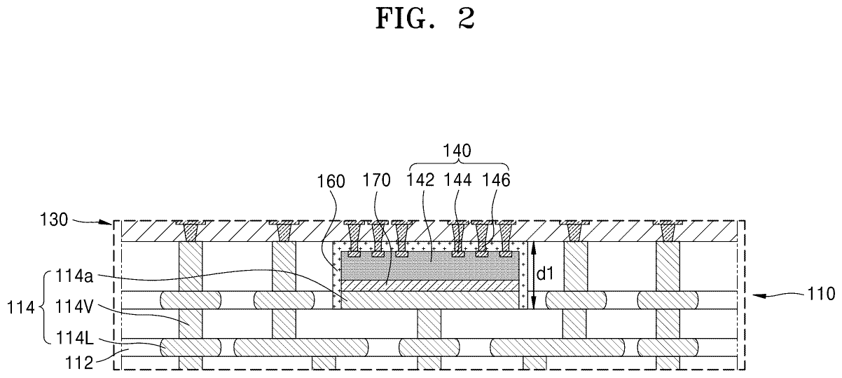

FIG. 2 is an enlarged cross-sectional view of portion EX1 of FIG. 1.

Referring to FIGS. 1 and 2, a semiconductor package 100 may include a ceramic substrate 110, a lower redistribution structure 120, an upper redistribution structure 130, a first semiconductor chip ch1, and a second semiconductor chip ch2.

The ceramic substrate 110 may include a plurality of first insulating layers 112 and a first circuit wiring layer 114 disposed between the plurality of first insulating layers 112. In embodiments, the plurality of first insulating layers 112 may include a low-temperature firing dielectric. For example, the plurality of first insulating layers 112 may contain aluminum oxide (Al₂O₃).

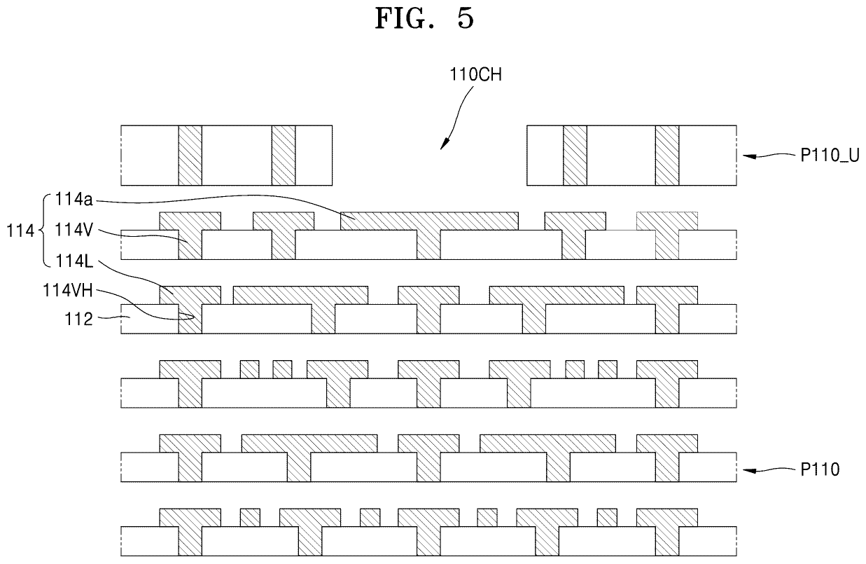

The first circuit wiring layer 114 may include a first wiring layer 114L, an upper wiring layer 114a, and a first via 114V. The first wiring layer 114L may extend in a horizontal direction between the plurality of first insulating layers 112 and may be arranged at a plurality of vertical levels, as illustrated. The first via 114V may be disposed inside a via hole (114VH, see FIG. 5) penetrating the plurality of first insulating layers 112 and may connect the plurality of first wiring layers 114L to each other between the plurality of first wiring layers 114L disposed at different vertical levels. In embodiments, the first wiring layer 114L and the first via 114V may include silver (Ag) or tungsten (W). The upper wiring layer 114a may be formed within a cavity 110C. A bridge chip structure 140 (FIG. 2) may be disposed on the upper wiring layer 114a.

In embodiments, the ceramic substrate 110 may be formed by forming a first wiring layer 114L and a first via 114V constituting the first circuit wiring layer 114 on each of the plurality of first insulating layers 112, stacking the plurality of first insulating layers 112, and then performing low-temperature co-firing on the first insulating layers 112 and the first circuit wiring layer 114. For example, the co-firing temperature may range from about 700° C. to about 1100° C. The first wiring layer 114L may have a rounded side surface. In the process of forming the first circuit wiring layer 114 on the plurality of first insulating layers 112 and laminating and firing the plurality of first insulating layers 112, the side surface of the first wiring layer 114L may be rounded, as illustrated in FIG. 2.

In embodiments, the ceramic substrate 110 may include a cavity 110C. The cavity 110C may be formed at the upper end of the ceramic substrate 110. The cavity 110C may be formed to have a predetermined depth at the upper end of the ceramic substrate 110. For example, the vertical depth d₁ (FIG. 2) of the cavity 110C may range from about 80 μm to about 200 μm. In the semiconductor package 100 of the inventive concept, the ceramic substrate 110 is manufactured by stacking and firing a plurality of conductive sheets (P110, see FIG. 5), thereby forming a deep vertical depth d₁ of the cavity 110C.

In embodiments, the semiconductor package 100 may include a bridge chip structure 140. The bridge chip structure 140 may be accommodated in the cavity 110C of the ceramic substrate 110. The bridge chip structure 140 may be disposed on the upper wiring layer 114a of the ceramic substrate 110. The bridge chip structure 140 may be attached to the upper wiring layer 114a by an adhesive film 170 provided between the bridge chip structure 140 and the upper wiring layer 114a. The adhesive film 170 may include, for example, a die attach film.

The bridge chip structure 140 may include a bridge chip 142, an upper bridge pad 144, and a bridge pillar 146. The bridge chip 142 may electrically connect a plurality of semiconductor chips. For example, the bridge chip 142 may electrically connect the first semiconductor chip ch1 and the second semiconductor chip ch2 to each other.

The upper bridge pad 144 and the bridge pillar 146 may electrically connect the bridge chip 142 to the plurality of semiconductor chips ch1 and ch2. For example, one or more upper bridge pads 144 and bridge pillars 146 may electrically connect the bridge chip 142 and the first semiconductor chip ch1 to each other. In addition, one or more upper bridge pads 144 and bridge pillars 146 may electrically connect the bridge chip 142 to the second semiconductor chip ch2. The upper bridge pad 144 and the bridge pillar 146 may include at least one of copper (Cu), nickel (Ni), gold (Au), platinum (Pt), titanium (Ti), chromium (Cr), or alloys thereof.

In embodiments, the semiconductor package 100 may further include an encapsulation layer 160. The encapsulation layer 160 may fill the inside of the cavity 110C of the ceramic substrate 110. In detail, the encapsulation layer 160 may be formed to cover the bridge chip structure 140 accommodated inside the cavity 110C of the ceramic substrate 110. The upper surface of the encapsulation layer 160 may be at the same level as the upper surface of the ceramic substrate 110 (i.e., the upper surface of the encapsulation layer 160 and the upper surface of the ceramic substrate 110 are co-planar).

In embodiments, the encapsulation layer 160 may be made of ceramic material, resin, or a combination thereof. In addition, the encapsulation layer 160 may be formed from a thermosetting resin such as an epoxy resin, a thermoplastic resin such as polyimide, or a resin containing a reinforcing material such as an inorganic filler, in detail, ajinomoto build-up film (DBF), FR-4, BT, etc., but is not limited thereto, and the encapsulation layer 160 may be formed from a molding material, such as epoxy mold compound (EMC) or a photosensitive material, such as photoimagable encapsulant (PIE).

In embodiments, the bridge chip structure 140 may further include one or more structures selected from a capacitor, an inductor, and a semiconductor switch (an intelligent power device (IPD)). For example, the bridge chip structure 140 may further include a Si capacitor. The capacitor, inductor, semiconductor switch, etc., may be accommodated in the cavity 110C of the ceramic substrate 110. The capacitor, inductor, semiconductor switch, etc., may be placed at the same vertical level as the bridge chip 142 within the cavity 110C.

The lower redistribution structure 120 may be disposed on the lower surface of the ceramic substrate 110. The lower redistribution structure 120 may include a plurality of second insulating layers 122 and a second circuit wiring layer 124 disposed between the plurality of second insulating layers 122. The lower redistribution structure 120 may be a redistribution substrate formed through a redistribution process. However, without being limited thereto, the lower redistribution structure 120 may correspond to any one of a printed circuit board (PCB), a metal core PCB (MCPCB), a metal PCB (MPCB), and a flexible PCB (FPCB).

In embodiments, the plurality of second insulating layers 122 may include a polymer material, for example, photo imageable dielectric (PID), photosensitive polyimide (PSPI), glass fiber-cured epoxy resin, polyimide resin, Teflon resin, etc.

The second circuit wiring layer 124 may include a second wiring layer 124L and a second via 124V. The second wiring layer 124L may extend in the horizontal direction between the plurality of second insulating layers 122 and may be arranged at a plurality of vertical levels. The second via 124V may connect the plurality of second wiring layers 124L disposed at different vertical levels to each other. In embodiments, the second wiring layer 124L and the second via 124V may include at least one of copper (Cu), nickel (Ni), gold (Au), platinum (Pt), titanium (Ti), chromium (Cr), or alloys thereof. The second circuit wiring layer 124 may be electrically connected to the first circuit wiring layer 114 of the ceramic substrate 110.

The upper redistribution structure 130 may be disposed on the ceramic substrate 110. The upper redistribution structure 130 may include a plurality of third insulating layers 132 and a third circuit wiring layer 134 disposed between the plurality of third insulating layers 132. The upper redistribution structure 130 may be a redistribution substrate formed through a redistribution process. However, without being limited thereto, the upper redistribution structure 130 may correspond to any one of a PCB, an MCPCB, an MPCB, and an FPCB.

In embodiments, the plurality of third insulating layers 132 may include polymer materials, (for example, PID, PSP), glass fiber-cured epoxy resin, polyimide resin, Teflon resin, etc.

The third circuit wiring layer 134 may include a third wiring layer 134L and a third via 134V. The third wiring layer 134L may extend in the horizontal direction between the plurality of third insulating layers 132 and may be disposed at a plurality of vertical levels. The third via 134V may connect the plurality of third wiring layers 134L to each other between the plurality of third wiring layers 134L disposed at different vertical levels. In embodiments, the third wiring layer 134L and the third via 134V may include at least one of copper (Cu), nickel (Ni), gold (Au), platinum (Pt), titanium (Ti), chromium (Cr), or alloys thereof. The third circuit wiring layer 134 may be electrically connected to the first circuit wiring layer 114 of the ceramic substrate 110.

In embodiments, the upper redistribution structure 130 may further include a lower connection pad (not shown). The lower connection pad may be disposed at the interface of the upper redistribution structure 130 and the ceramic substrate 110. The lower connection pad may be electrically connected to the third via 134V of the upper redistribution structure 130.

In embodiments, the semiconductor package 100 may include a first pad 152 disposed on the lower surface of the lower redistribution structure 120 and a second pad 154 disposed on the upper surface of the upper redistribution structure 130.

The first pad 152 may be electrically connected to the second circuit wiring layer 124 of the lower redistribution structure 120. The first pad 152 may include a pad layer and a capping metal layer disposed on an outer surface of the pad layer. For example, the pad layer may include at least one of copper (Cu), nickel (Ni), gold (Au), platinum (Pt), titanium (Ti), chromium (Cr), or alloys thereof, and the capping metal layer may include at least one of nickel (Ni), gold (Au), platinum (Pt), or an alloy thereof. An external connection terminal such as a solder ball having a relatively large size may be disposed on the capping metal layer of the first pad 152.

The second pad 154 may be electrically connected to the third circuit wiring layer 134 of the upper redistribution structure 130 and may include a pad layer and a capping metal layer disposed on the outer surface of the pad layer. For example, the pad layer may include at least one of copper (Cu), nickel (Ni), gold (Au), platinum (Pt), titanium (Ti), chromium (Cr), or alloys thereof, and the capping metal layer may include at least one of nickel (Ni), gold (Au), platinum (Pt), or an alloy thereof.

A connection bump 156 may be disposed on the second pad 154. The connection bump 156 may be disposed to contact the second pad 154. The connection bump 156 may electrically connect the first semiconductor chip ch1 and the second semiconductor chip ch2 to the upper redistribution structure 130. Through the connection bump 156, at least one of a control signal, a power signal, and a ground signal for operation of the first semiconductor chip ch1 and/or the second semiconductor chip ch2 may be provided from the outside (i.e., external to the semiconductor package 100), data signals to be stored in the first semiconductor chip ch1 and/or the second semiconductor chip ch2 may be provided from the outside, or data stored in the first semiconductor chip ch1 and/or the second semiconductor chip ch2 may be provided to the outside. For example, the connection bump 156 may be made of a pillar structure, a ball structure, or a solder layer.

The first semiconductor chip ch1 and the second semiconductor chip ch2 may be mounted on the upper redistribution structure 130. For example, the first semiconductor chip ch1 and the second semiconductor chip ch2 may be mounted on the upper redistribution structure 130 through the connection bump 156 using a flip chip method. Although not shown in FIG. 1, in some embodiments, an underfill material layer surrounding the connection bump 156 may be disposed between the plurality of semiconductor chips ch1 and ch2 and the upper redistribution structure 130. The first semiconductor chip ch1 and the second semiconductor chip ch2 may be arranged side-by-side, as illustrated. The first semiconductor chip ch1 and the second semiconductor chip ch2 may be arranged to be spaced apart in the horizontal direction, as illustrated. In FIG. 1, the semiconductor package 100 is shown as including two semiconductor chips ch1 and ch2, but the inventive concept is not limited thereto. The semiconductor package 100 may include three or more semiconductor chips and may include semiconductor chips with a stacked structure.

The first semiconductor chip ch1 may be a logic semiconductor chip. For example, the first semiconductor chip ch1 may include a logic semiconductor chip, such as a central processing unit (CPU), a graphics processing unit (GPU), an application processor (AP), an application specific integrated circuit (ASIC), or other processing chips. However, the first semiconductor chip ch1 is not limited thereto, and the first semiconductor chip ch1 may include a volatile memory semiconductor chip, such as dynamic random access memory (DRAM) or static random access memory (SRAM), or a non-volatile memory semiconductor chip, such as phase-change random access memory (PRAM), magnetoresistive random access memory (MRAM), ferroelectric random access memory (FeRAM), or resistive random access memory (RRAM).

The second semiconductor chip ch2 may be a memory semiconductor chip. For example, the second semiconductor chip ch2 may be a volatile memory semiconductor chip, such as DRAM or SRAM, or a non-volatile memory semiconductor chip, such as PRAM, MRAM, FeRAM, or RRAM. However, the second semiconductor chip ch2 is not limited thereto, and the second semiconductor chip ch2 may include a logic semiconductor chip, such as a CPU, a GPU, an AP, an ASIC, or other processing chips.

The ceramic substrate 110 has a low coefficient of thermal expansion (CTE) and is effective in preventing warpage of the semiconductor package 100 due to material characteristics of the ceramic substrate 110. In addition, the manufacturing process time of the semiconductor package 100 including the ceramic substrate 110 of the inventive concept may be shortened. In addition, due to the characteristics of the ceramic material, a high temperature process may be performed, so the functional characteristics of the semiconductor package 100 may be improved.

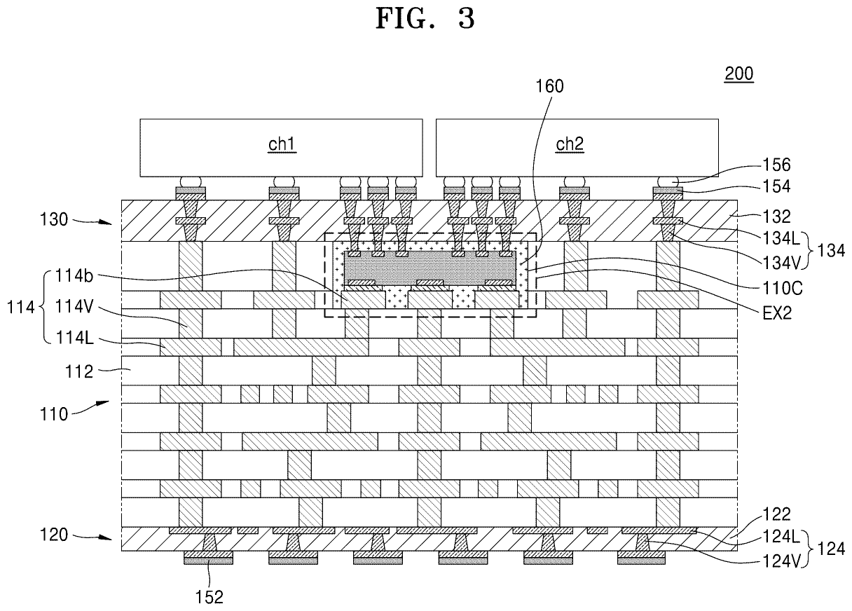

FIG. 3 is a cross-sectional view schematically showing a semiconductor package according to an embodiment.

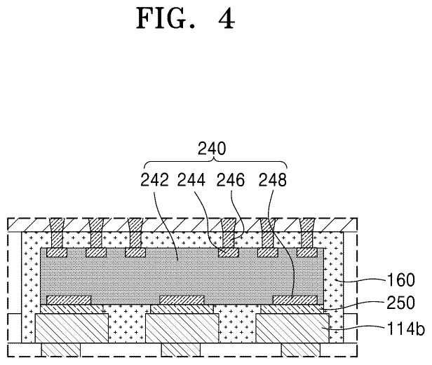

FIG. 4 is an enlarged cross-sectional view of portion EX2 of FIG. 3.

Referring to FIGS. 3 and 4, a semiconductor package 200 may include a ceramic substrate 110, a lower redistribution structure 120, an upper redistribution structure 130, a first semiconductor chip ch1, and a second semiconductor chip ch2. Among the configurations of the semiconductor package 200, descriptions of configurations that are the same as or correspond to the semiconductor package 100 described with reference to FIGS. 1 and 2 may be omitted.

The ceramic substrate 110 may include a plurality of first insulating layers 112 and a first circuit wiring layer 114 disposed between the plurality of first insulating layers 112. In embodiments, the plurality of first insulating layers 112 may include a low-temperature firing dielectric, for example, aluminum oxide (Al₂O₃). The ceramic substrate 110 may include a cavity 110C. The cavity 110C may be formed at the upper end of the ceramic substrate 110. The cavity 110C may be formed to have a predetermined depth at the upper end of the ceramic substrate 110C.

The first circuit wiring layer 114 may include a first wiring layer 114L, an upper wiring layer 114b, and a first via 114V. The first wiring layer 114L may extend in the horizontal direction between the plurality of first insulating layers 112 and may be disposed at a plurality of vertical levels. The first via 114V may be disposed inside a via hole (114VH, see FIG. 5) penetrating the plurality of first insulating layers 112 and may connect the plurality of first wiring layers 114L to each other between the plurality of first wiring layers 114L disposed at different vertical levels. In embodiments, the first wiring layer 114L and the first via 114V may include silver (Ag) or tungsten (W). The upper wiring layer 114b may be formed within the cavity 110C. A bridge chip structure 240 may be disposed on the upper wiring layer 114b.

In embodiments, the ceramic substrate 110 may be formed by forming a first wiring layer 114L and a first via 114V constituting the first circuit wiring layer 114 on each of the plurality of first insulating layers 112, stacking a plurality of first insulating layers 112, and then performing low-temperature co-firing on the first insulating layers 112 and the first circuit wiring layer 114. For example, the co-firing temperature may range from about 700° C. to about 1100° C.

In embodiments, the semiconductor package 200 may include a bridge chip structure 240. The bridge chip structure 240 may be accommodated within the cavity 110C of the ceramic substrate 110. The bridge chip structure 240 may be disposed on the upper wiring layer 114b of the ceramic substrate 110. The bridge chip structure 240 may be mounted on the upper wiring layer 114b by a connection pad 250 provided between the bridge chip structure 240 and the upper wiring layer 114b. For example, the connection pad 250 may be formed of a pillar structure, a ball structure, or a solder layer.

The bridge chip structure 240 may include a bridge chip 242, an upper bridge pad 244, a bridge pillar 246, and a lower bridge pad 248. The bridge chip 242 may electrically connect a plurality of semiconductor chips. For example, the bridge chip 242 may electrically connect the first semiconductor chip ch1 and the second semiconductor chip ch2 to each other. The upper bridge pad 244 and the bridge pillar 246 may electrically connect the bridge chip 242 to the plurality of semiconductor chips ch1 and ch2. For example, one or more upper bridge pads 244 and bridge pillars 246 may electrically connect the bridge chip 242 to the first semiconductor chip ch1. In addition, one or more upper bridge pads 244 and bridge pillars 246 may electrically connect the bridge chip 242 to the second semiconductor chip ch2. The upper bridge pad 244, the lower bridge pad 248, and the bridge pillar 246 may include at least one of copper (Cu), nickel (Ni), gold (Au), platinum (Pt), titanium (Ti), chromium (Cr), or alloys thereof.

In embodiments, the bridge chip 242 may include a Through Silicon Via (TSV). The TSV may extend through the bridge chip 242 to the ceramic substrate 110. The TSV may electrically connect the upper bridge pad 244 and the lower bridge pad 248 to each other. Therefore, control signals such as input/output data signals and command signals may be transmitted between the first semiconductor chip ch1, the second semiconductor chip ch2, and the bridge chip 242 through the TSV, the upper bridge pad 244, the bridge pillar 246, and the lower bridge pad 248.

In embodiments, the semiconductor package 200 may further include an encapsulation layer 160. The encapsulation layer 160 may fill the inside of the cavity 110C of the ceramic substrate 110. In detail, the encapsulation layer 160 may be formed to cover the bridge chip structure 240 accommodated inside the cavity 110C of the ceramic substrate 110. In detail, the encapsulation layer 160 may be formed to cover the upper wiring layer 114b, the bridge chip 242, and the connection pad 250. In detail, the encapsulation layer 160 may be formed to cover the upper wiring layer 114a, the bridge chip 242, and the adhesive film 170.

In embodiments, the upper surface of the encapsulation layer 160 may be at the same level as the top surface of the ceramic substrate 110 (i.e., the upper surface of the encapsulation layer 160 and the top surface of the ceramic substrate 110 are co-planar). The encapsulation layer 160 may be made of ceramic material, resin, or a combination thereof.

The lower redistribution structure 120 may be disposed on the lower surface of the ceramic substrate 110. The lower redistribution structure 120 may include a plurality of second insulating layers 122 and a second circuit wiring layer 124 disposed between the plurality of second insulating layers 122. The lower redistribution structure 120 may be a redistribution substrate formed through a redistribution process. However, the inventive concept is not limited thereto, and the lower redistribution structure 120 may correspond to any one of a PCB, an MCPCB, an MPCB, and an FPCB.

The upper redistribution structure 130 may be disposed on the ceramic substrate 110. The upper redistribution structure 130 may include a plurality of third insulating layers 132 and a third circuit wiring layer 134 disposed between the plurality of third insulating layers 132. The upper redistribution structure 130 may be a redistribution substrate formed through a redistribution process. However, the inventive concept is not limited thereto, and the upper redistribution structure 130 may correspond to any one of a printed PCB, an MCPCB, an MPCB, and an FPCB.

In embodiments, the semiconductor package 200 may include a first pad 152 disposed on the lower surface of the lower redistribution structure 120 and a second pad 154 disposed on the upper surface of the upper redistribution structure 130. A connection bump 156 may be disposed on the second pad 154. The connection bump 156 may be disposed to contact the second pad 154. The connection bump 156 may electrically connect the first semiconductor chip ch1 and the second semiconductor chip ch2 to the upper redistribution structure 130. For example, the connection bump 156 may be formed of a pillar structure, a ball structure, or a solder layer.

The first semiconductor chip ch1 and the second semiconductor chip ch2 may be mounted on the upper redistribution structure 130. For example, the first semiconductor chip ch1 and the second semiconductor chip ch2 may be mounted on the upper redistribution structure 130 using a flip chip method through the connection bump 156.

The first semiconductor chip ch1 may be a logic semiconductor chip. For example, the first semiconductor chip ch1 may include a logic semiconductor chip, such as a CPU, a GPU, an AP, an ASIC, or other processing chips. However, the first semiconductor chip ch1 is not limited thereto and may include a memory semiconductor chip.

The second semiconductor chip ch2 may be a memory semiconductor chip. For example, the second semiconductor chip ch2 may be a volatile memory semiconductor chip, such as DRAM or SRAM, or a non-volatile memory semiconductor chip, such as PRAM, MRAM, FeRAM, or RRAM. However, the second semiconductor chip ch2 is not limited to thereto and may include a logic semiconductor chip.

In embodiments, the bridge chip structure 240 may further include one or more structures selected from a capacitor, an inductor, and a semiconductor switch. Capacitors, inductors, semiconductor switches, etc., may be accommodated in the cavity 110C. The capacitor, inductor, semiconductor switch, etc., may be placed at the same vertical level as the bridge chip 242 within the cavity 110C.

The ceramic substrate 110 has a low CTE and is effective in preventing warpage of the semiconductor package 200 due to material characteristics of the ceramic substrate 110. In addition, the manufacturing process time of the semiconductor package 200 including the ceramic substrate 110 of the inventive concept may be shortened. In addition, due to the characteristics of the ceramic material, a high temperature process may be performed, so the functional characteristics of the semiconductor package 200 may be improved.

FIGS. 5 to 11 are cross-sectional views schematically showing a method of manufacturing a semiconductor package, according to an embodiment.

Referring to FIG. 5, a plurality of conductive sheets P110 may be stacked. In embodiments, each of the plurality of conductive sheets P110 may include a first insulating layer 112, a first wiring layer 114L disposed on the upper surface of the first insulating layer 112, and a first via 114V disposed in a via hole 114VH penetrating the first insulating layer 112.

An uppermost conductive sheet P110_U may include a cavity hole 110CH. The conductive sheet P110 disposed below the uppermost conductive sheet P110_U may include an upper wiring layer 114a.

In embodiments, the first insulating layer 112 may be formed using a low-temperature firing dielectric and may include, for example, aluminum oxide (Al₂O₃). In embodiments, the first wiring layer 114L may be formed using a first conductive material, and the first conductive material may include silver or tungsten. In some embodiments, the first wiring layer 114L may be formed by applying or printing silver paste on the first insulating layer 112.

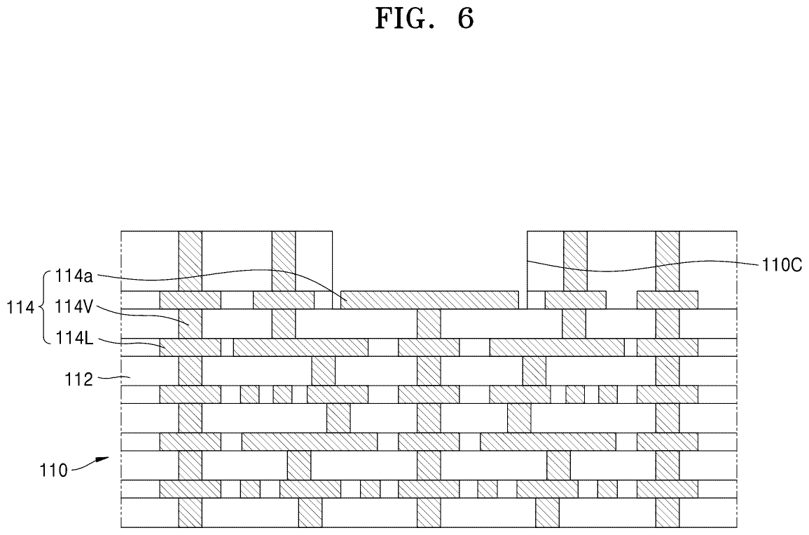

Referring to FIG. 6, the ceramic substrate 110 may be formed by firing a plurality of conductive sheets P110. In embodiments, the firing temperature of the plurality of conductive sheets P110 may be about 700° C. to about 1100° C. In embodiments, the first wiring layer 114L, the upper wiring layer 114a, and the first via 114V stacked in the vertical direction during the firing process may constitute the first circuit wiring layer 114.

A cavity 110C may be formed in the upper part of the ceramic substrate 110. The cavity 110C may be formed to have a predetermined depth at the upper end of the ceramic substrate 110C. For example, the vertical depth of the cavity 110C may range from about 80 μm to about 200 μm.

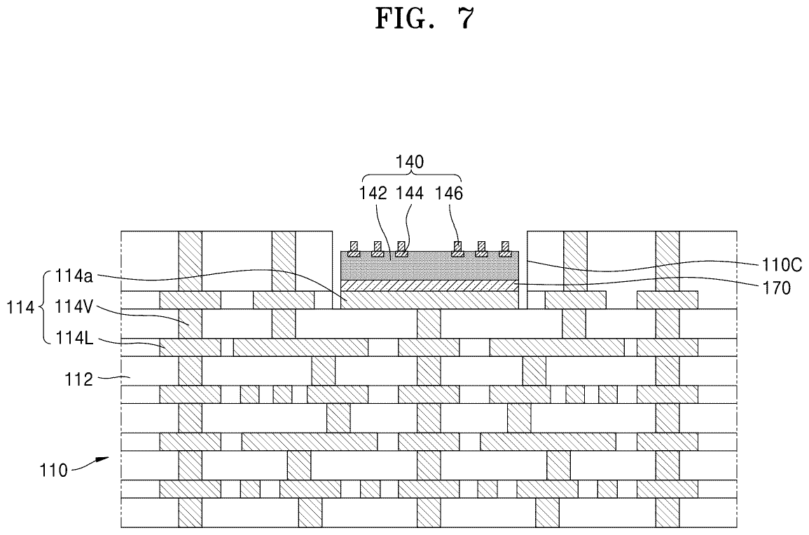

Referring to FIG. 7, the bridge chip structure 140 may be mounted. The bridge chip structure 140 may be disposed within the cavity 110C of the ceramic substrate 110. The bridge chip structure 140 may be attached to the upper wiring layer 114a by an adhesive film 170 provided between the bridge chip structure 140 and the upper wiring layer 114a. The adhesive film 170 may include, for example, a die attach film. The bridge chip structure 140 may include a bridge chip 142, an upper bridge pad 144, and a bridge pillar 146.

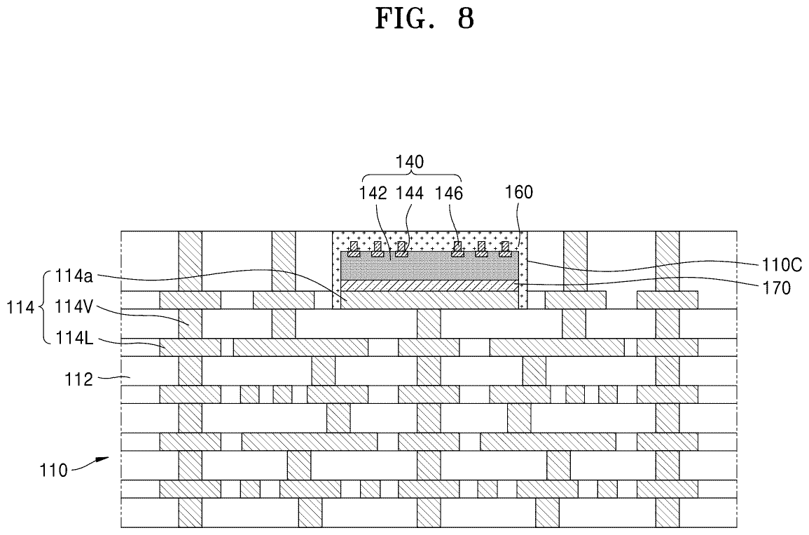

Referring to FIG. 8, an encapsulation layer 160 may be formed. The encapsulation layer 160 may fill the inside of the cavity 110C of the ceramic substrate 110. In detail, the encapsulation layer 160 may be formed to cover the bridge chip structure 140 accommodated inside the cavity 110C of the ceramic substrate 110. The encapsulation layer 160 may be made of ceramic material, resin, or a combination thereof.

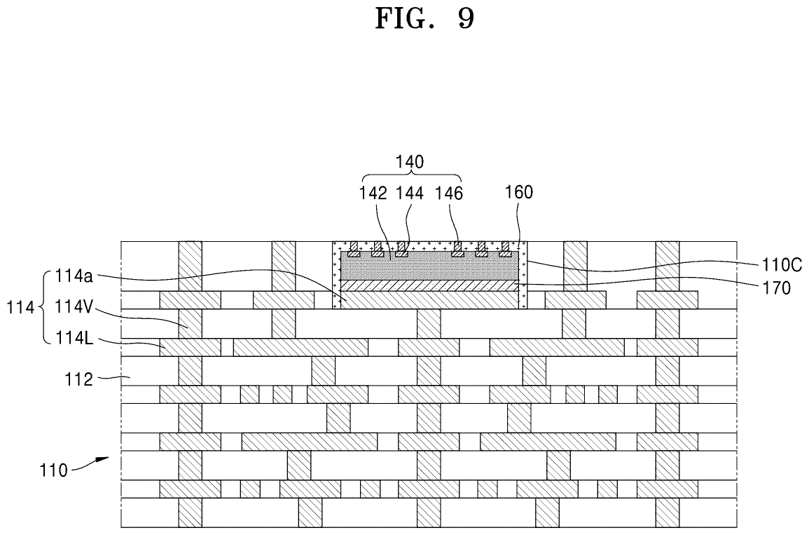

Referring to FIG. 9, the upper surfaces of the ceramic substrate 110 and the encapsulation layer 160 may be polished. The upper surfaces of the ceramic substrate 110 and the encapsulation layer 160 may be formed at the same level (i.e., the upper surface of the ceramic substrate 110 and the upper surface of the encapsulation layer 160 are co-planar). The first via 114V of the ceramic substrate 110 may be exposed. The bridge pillar 146 of the bridge chip structure 140 may be exposed.

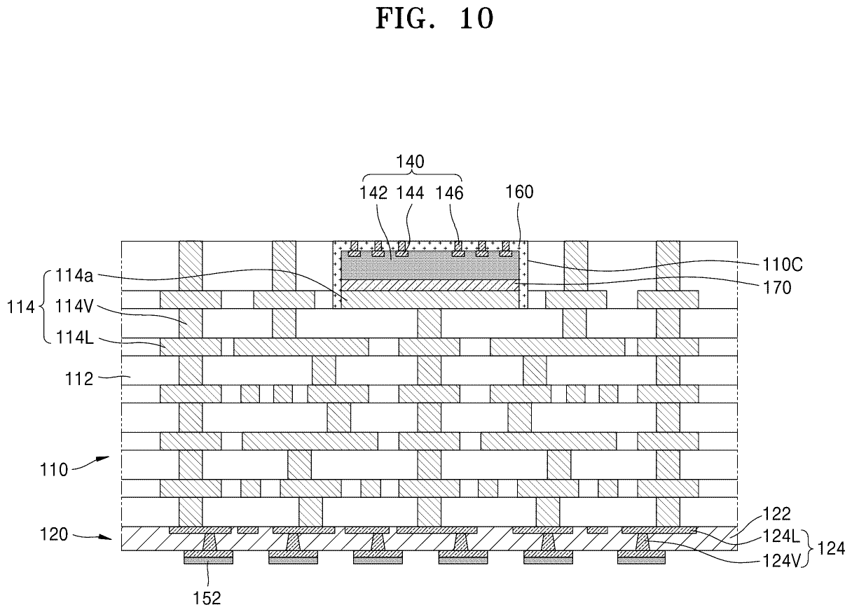

Referring to FIG. 10, the lower redistribution structure 120 may be formed on the lower surface of the ceramic substrate 110. The lower redistribution structure 120 may include a second insulating layer 122 and a second circuit wiring layer 124.

In embodiments, to form the lower redistribution structure 120, the processes of forming a plurality of second insulating layers 122 and forming a plurality of second wiring layers 124L may be repeatedly performed.

In some embodiments, the second insulating layer 122 may be formed using a polymer material, for example, photo imageable dielectric (PID), photosensitive polyimide (PSPI), glass fiber-cured epoxy resin, polyimide resin, Teflon resin, etc. In some embodiments, forming the plurality of second wiring layers 124L may be performed using at least one of an electrolytic plating process, an electroless plating process, a sputtering process, and an evaporation process.

For example, in the process of forming the lower redistribution structure 120, a second via 124V may be formed to connect the second wiring layers 124L disposed at different vertical levels to each other in the process of forming the plurality of second wiring layers 124L. For example, a via hole may be formed in the second insulating layer 122, a second wiring layer 124L may be formed on the second insulating layer 122, and a portion of the second wiring layer 124L that fills the inside of the via hole may be referred to as the second via 124V. Thereafter, a first pad 152 electrically connected to the second circuit wiring layer 124 may be formed on the bottom surface of the lower redistribution structure 120.

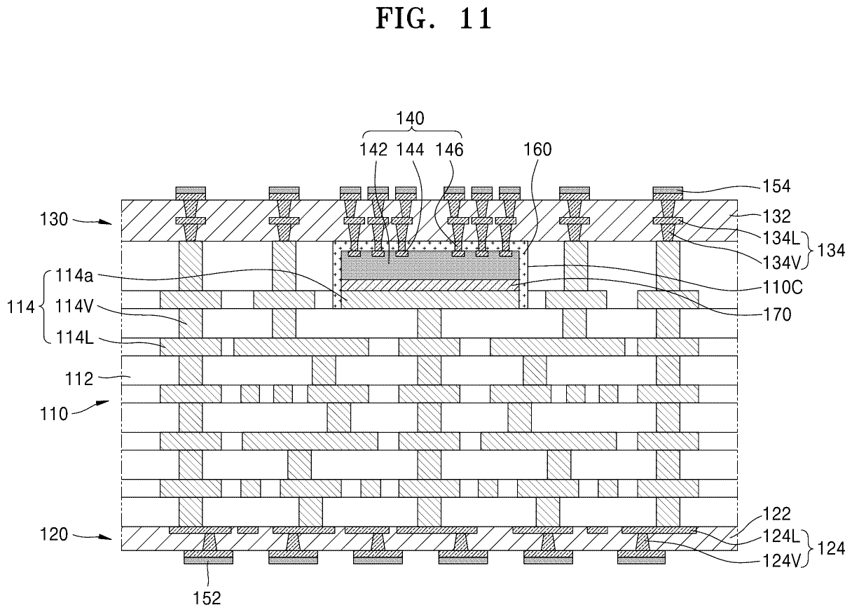

Referring to FIG. 11, the upper redistribution structure 130 may be formed on the upper surface of the ceramic substrate 110. The upper redistribution structure 130 may include a third insulating layer 132 and a third circuit wiring layer 134.

In embodiments, to form the upper redistribution structure 130, the processes of forming a plurality of third insulating layers 132 and forming a plurality of third wiring layers 134L may be repeatedly performed.

In embodiments, the third insulating layer 132 may be formed using a polymer material, for example, PID, PSPI, glass fiber-cured epoxy resin, polyimide resin, TEFLON® brand resin, etc. In some embodiments, forming the plurality of third wiring layers 134L may be performed using at least one of an electrolytic plating process, an electroless plating process, a sputtering process, or an evaporation process.

For example, in the process of forming the upper redistribution structure 130, a third via 134V may be formed to connect the third wiring layers 134L disposed at different vertical levels to each other in the process of forming a plurality of third wiring layers 134L. For example, the via hole may be formed in the third insulating layer 132, the third wiring layer 134L may be formed on the third insulating layer 132, and a portion of the third wiring layer 134L that fills the inside of the via hole may be referred to as the third via 134V. Thereafter, a second pad 154 electrically connected to the third circuit wiring layer 134 may be formed on the upper surface of the upper redistribution structure 130.

Thereafter, referring again to FIG. 1, the first semiconductor chip ch1 and the second semiconductor chip ch2 may be mounted on the upper redistribution structure 130 using the connection bump 156. The connection bump 156 may electrically connect the first semiconductor chip ch1 and the second semiconductor chip ch2 to the upper redistribution structure 130.

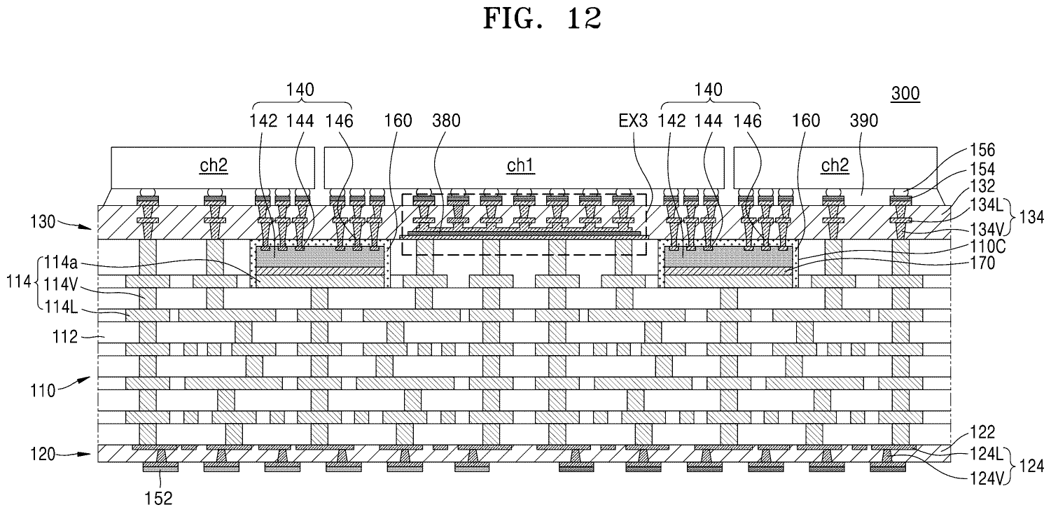

FIG. 12 is a cross-sectional view schematically showing a semiconductor package according to an embodiment.

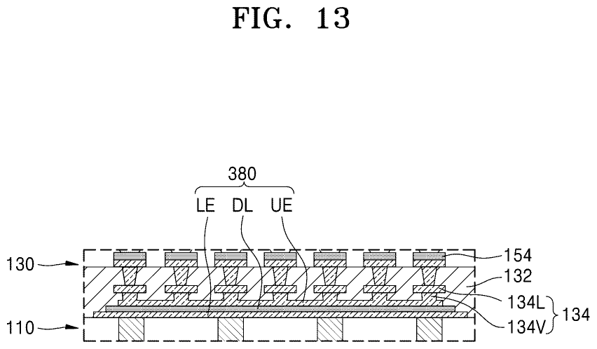

FIG. 13 is an enlarged cross-sectional view of portion EX3 of FIG. 12.

Referring to FIGS. 12 and 13, a semiconductor package 300 may include a ceramic substrate 110, a lower redistribution structure 120, an upper redistribution structure 130, a first semiconductor chip ch1, a plurality of second semiconductor chips ch2, and a capacitor structure 380. Among the configurations of the semiconductor package 300, descriptions of configurations that are the same as or correspond to the semiconductor package 100 described with reference to FIGS. 1 and 2 may be omitted.

The ceramic substrate 110 may include a plurality of first insulating layers 112 and a first circuit wiring layer 114 disposed between the plurality of first insulating layers 112. In embodiments, the plurality of first insulating layers 112 may include a low-temperature firing dielectric, for example, aluminum oxide (Al₂O₃). The ceramic substrate 110 may include a plurality of cavities 110C. Each cavity 110C may be formed at the upper end of the ceramic substrate 110. Each cavity 110C may be formed to have a predetermined depth at the upper end of the ceramic substrate 110. The plurality of cavities 110C may be formed at the same vertical level and may have the same depth but are not limited thereto.

The first circuit wiring layer 114 may include a first wiring layer 114L, an upper wiring layer 114b, and a first via 114V. The first wiring layer 114L may extend in a first (e.g., a horizontal) direction between the plurality of first insulating layers 112 and may be arranged at a plurality of vertical levels. The first via 114V may be disposed inside a via hole (114VH, see FIG. 5) penetrating the plurality of first insulating layers 112 and may connect the plurality of first wiring layers 114L to each other between the plurality of first wiring layers 114L disposed at different vertical levels. In embodiments, the first wiring layer 114L and the first via 114V may include silver (Ag) or tungsten (W). The upper wiring layer 114a may be formed within a cavity 110C. A bridge chip structure 140 may be disposed on the upper wiring layer 114a.

In embodiments, the ceramic substrate 110 may be formed by forming a first wiring layer 114L and a first via 114V constituting the first circuit wiring layer 114 on each of the plurality of first insulating layers 112, stacking the plurality of first insulating layers 112, and then performing low-temperature co-firing on the first insulating layers 112 and the first circuit wiring layer 114. For example, the co-firing temperature may range from about 700° C. to about 1100° C.

In embodiments, the semiconductor package 300 may include bridge chip structures 140. The plurality of bridge chip structures 140 may each be accommodated in the plurality of cavities 110C of the ceramic substrate 110. Each bridge chip structure 140 may be disposed on the upper wiring layer 114a of the ceramic substrate 110. The descriptions regarding the configuration and characteristics of the bridge chip structure 140 may be replaced with descriptions already given with reference to FIGS. 1 and 2. Additionally, the semiconductor package 300 may include the bridge chip structure 240 described with reference to FIGS. 3 and 4.

In embodiments, the semiconductor package 300 may further include an encapsulation layer 160. The encapsulation layer 160 may fill the inside of the cavity 110C of the ceramic substrate 110. In detail, the encapsulation layer 160 may be formed to cover the bridge chip structure 140 accommodated inside the cavity 110C of the ceramic substrate 110. The upper surface of the encapsulation layer 160 may be at the same level as the upper surface of the ceramic substrate 110 (i.e., the upper surface of the encapsulation layer 160 and the upper surface of the ceramic substrate 110 are co-planar). The encapsulation layer 160 may be made of ceramic material, resin, or a combination thereof.

The lower redistribution structure 120 may be disposed on the lower surface of the ceramic substrate 110. The lower redistribution structure 120 may include a plurality of second insulating layers 122 and a second circuit wiring layer 124 disposed between the plurality of second insulating layers 122. The lower redistribution structure 120 may be a redistribution substrate formed through a redistribution process. However, without being limited thereto, the lower redistribution structure 120 may correspond to any one of a PCB, an MCPCB, an MPCB, and an FPCB.

The upper redistribution structure 130 may be disposed on the ceramic substrate 110. The upper redistribution structure 130 may include a plurality of third insulating layers 132 and a third circuit wiring layer 134 disposed between the plurality of third insulating layers 132. The upper redistribution structure 130 may be a redistribution substrate formed through a redistribution process. However, without being limited thereto, the upper redistribution structure 130 may correspond to any one of a PCB, an MCPCB, an MPCB, and an FPCB.

In embodiments, the semiconductor package 300 may include a first pad 152 disposed on the lower surface of the lower redistribution structure 120 and a second pad 154 disposed on the upper surface of the upper redistribution structure 130. A connection bump 156 may be disposed on the second pad 154. The connection bump 156 may be disposed to contact the second pad 154. The connection bump 156 may electrically connect the first semiconductor chip ch1 and the second semiconductor chip ch2 to the upper redistribution structure 130. For example, the connection bump 156 may be formed of a pillar structure, a ball structure, or a solder layer.

The first semiconductor chip ch1 and the second semiconductor chip ch2 may be mounted on the upper redistribution structure 130. For example, the first semiconductor chip ch1 and the second semiconductor chip ch2 may be mounted on the upper redistribution structure 130 through the connection bump 156 using a flip chip method. In some embodiments, an underfill material layer 390 surrounding the connection bump 156 may be disposed between the first and second semiconductor chips ch1 and ch2 and the upper redistribution structure 130. The underfill material layer 390 may be made of, for example, an epoxy resin formed using a capillary under-fill method. In some embodiments, the underfill material layer 390 may be a non-conductive film (NCF).

The first semiconductor chip ch1 may be a logic semiconductor chip. For example, the first semiconductor chip ch1 may include a logic semiconductor chip, such as a CPU, a GPU, an AP, an ASIC, or other processing chips. However, the first semiconductor chip ch1 is not limited thereto and may include a memory semiconductor chip.

The second semiconductor chip ch2 may be a memory semiconductor chip. For example, the second semiconductor chip ch2 may be a volatile memory semiconductor chip, such as DRAM or SRAM, or a non-volatile memory semiconductor chip, such as PRAM, MRAM, FeRAM, or RRAM. In some embodiments, the second semiconductor chip ch2 may be a high bandwidth memory (HBM) chip that increases bandwidth by stacking DRAM in multiple layers. However, the first semiconductor chip ch2 is not limited thereto and may include a memory semiconductor chip.

The capacitor structure 380 may be provided at the interface between the ceramic substrate 110 and the upper redistribution structure 130. In addition, the capacitor structure 380 may be disposed adjacent to the first semiconductor chip ch1. For example, the capacitor structure 380 may be disposed between the first semiconductor chip ch1 and the ceramic substrate 110.

The capacitor structure 380 may include a lower electrode layer LE, a dielectric layer DL, and an upper electrode layer UE (FIG. 13) and may be a capacitor with a metal-insulator-metal (MIM) structure.

The lower electrode layer LE may be disposed on the upper surface of the ceramic substrate 110. For example, the lower electrode layer LE may be disposed at a vertical level higher than the plurality of first wiring layers 114L.

In embodiments, the lower electrode layer LE may include a first conductive material, and the first conductive material may include silver (Ag) or tungsten (W). The lower electrode layer LE may include the same material as that constituting the first circuit wiring layer 114. The lower electrode layer LE may be formed on the upper surface of the ceramic substrate 110 using a plating process, etc. The lower electrode layer LE may have a predetermined thickness. For example, the lower electrode layer LE may have a thickness ranging from about 1 μm to about 10 μm.

The dielectric layer DL may be disposed on the lower electrode layer LE on the ceramic substrate 110. In embodiments, the dielectric layer DL may include a high-k dielectric material. The high-k dielectric materials may refer to materials that have a dielectric constant greater than that of silicon oxide. In embodiments, the dielectric layer DL may include a material having a dielectric constant of about 5 or more, or about 10 or more. For example, the dielectric layer DL may include hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or combinations thereof, but the dielectric layer DL is not limited thereto.

The dielectric layer DL may have a thickness of, for example, about 1 μm to about 5 μm. As the dielectric layer DL is formed using a high dielectric constant dielectric material and is formed to a relatively thin thickness, the capacitor structure 380 may exhibit relatively high capacitance.

The upper electrode layer UE may be disposed on the upper surface of the dielectric layer DL. The upper electrode layer UE may include a second conductive material, and the second conductive material may be different from the first conductive material. For example, the second conductive material may include at least one of copper (Cu), nickel (Ni), gold (Au), platinum (Pt), titanium (Ti), chromium (Cr), or alloys thereof. However, the second conductive material is not limited thereto, and the first conductive material may be the same as the second conductive material. The upper electrode layer UE may include the same material as that constituting the third circuit wiring layer 134. The upper electrode layer UE may be formed on the upper surface of the dielectric layer DL using a plating process or the like. The upper electrode layer UE may have a predetermined thickness. For example, the upper electrode layer UE may have a thickness ranging from about 1 μm to about 10 μm.

In embodiments, the lower electrode layer LE of the capacitor structure 380 may be electrically connected to the first via 114V of the ceramic substrate 110. The lower electrode layer LE may be electrically connected to the first wiring layer 114L through the first via 114V. The upper electrode layer UE of the capacitor structure 380 may be electrically connected to the third via 134V of the upper redistribution structure 130. The upper electrode layer UE may be electrically connected to the third wiring layer 134L through the third via 134V. The lower electrode layer LE may include the same material as the first wiring layer 114L, and the upper electrode layer UE may include the same material as the third wiring layer 134L.

The ceramic substrate 110 has a low CTE and is effective in preventing warpage of the semiconductor package 300 due to material characteristics of the ceramic substrate 110. In addition, the manufacturing process time of the semiconductor package 300 including the ceramic substrate 110 of the inventive concept may be shortened. In addition, due to the characteristics of the ceramic material, a high temperature process may be performed, so the functional characteristics of the semiconductor package 300 may be improved.

In addition, because high-temperature processes are possible due to the characteristics of ceramic materials, the capacitor structure 380 may have the MIM structure. Therefore, by forming the capacitor structure 380 adjacent to the logic semiconductor chip, the power integrity (PI) characteristics of the logic semiconductor chip may be improved.

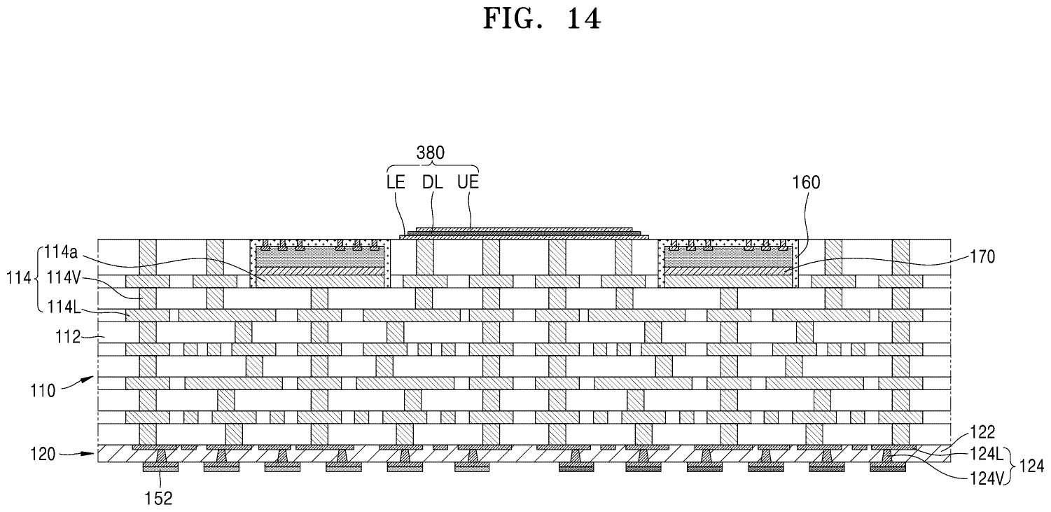

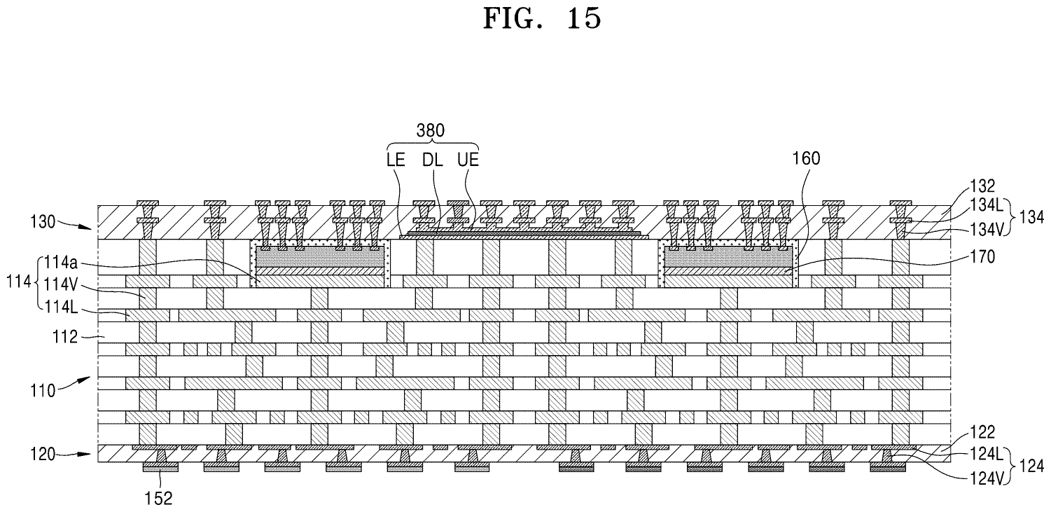

FIGS. 14 and 15 are cross-sectional views schematically showing a method of manufacturing a semiconductor package, according to an embodiment.

Referring to FIG. 14, a capacitor structure 380 may be formed on the ceramic substrate 110. The method of forming the ceramic substrate 110 and the lower redistribution structure 120 may be the same as described above with reference to FIGS. 5 to 10. The method of manufacturing a semiconductor package may be formed by sequentially stacking a lower electrode layer LE, a dielectric layer DL, and an upper electrode layer UE on the ceramic substrate 110.

In some embodiments, the lower electrode layer LE may be formed simultaneously in the process of forming the first circuit wiring layer 114. The dielectric layer DL may be formed on the lower electrode layer LE, and the upper electrode layer UE may be formed on the dielectric layer DL.

In embodiments, the dielectric layer DL may be formed by at least one of a chemical vapor deposition (CVD) process, a physical vapor deposition (PVD) process, an atomic layer deposition (ALD) process, a spin coating process, and a spray process using a high dielectric constant dielectric material.

Accordingly, the capacitor structure 380 having a MIM structure including the lower electrode layer LE, the dielectric layer DL, and the upper electrode layer UE may be formed.

Referring to FIG. 15, the upper redistribution structure 130 may be formed on the upper surface of the ceramic substrate 110. The upper redistribution structure 130 may cover the capacitor structure 380. The upper redistribution structure 130 may include a third insulating layer 132 and a third circuit wiring layer 134. The method of forming the upper redistribution structure 130 may be the same as that described above with reference to FIG. 11.

Referring again to FIG. 12, the first semiconductor chip ch1 and the second semiconductor chip ch2 may be mounted on the upper redistribution structure 130 using the connection bump 156. The connection bump 156 may electrically connect the first semiconductor chip ch1 and the second semiconductor chip ch2 to the upper redistribution structure 130.

An underfill material layer 390 surrounding the connection bump 156 may be disposed between the first and second semiconductor chips ch1 and ch2 and the upper redistribution structure 130. The underfill material layer 390 may be made of, for example, an epoxy resin formed using a capillary under-fill method.

While the inventive concept has been particularly shown and described with reference to embodiments thereof, it will be understood that various changes in form and details may be made therein without departing from the scope of the following claims.

What is claimed is:

1. A semiconductor package comprising:
a ceramic substrate having a cavity;
a lower redistribution structure on a lower surface of the ceramic substrate and electrically connected to the ceramic substrate;
an upper redistribution structure on an upper surface of the ceramic substrate and electrically connected to the ceramic substrate;
a plurality of semiconductor chips arranged in a first direction on the upper redistribution structure; and
a bridge chip structure in the cavity of the ceramic substrate and comprising a bridge chip electrically connecting the plurality of semiconductor chips to each other.

2. The semiconductor package of claim 1, wherein the bridge chip structure further comprises a bridge pillar and an upper bridge pad that electrically connect the bridge chip and the plurality of semiconductor chips to each other.

3. The semiconductor package of claim 2, wherein the bridge chip comprises a through silicon via (TSV) extending through the bridge chip to the ceramic substrate.

4. The semiconductor package of claim 3, wherein the bridge chip structure further comprises a lower bridge pad connected to the TSV of the bridge chip.

5. The semiconductor package of claim 1, further comprising an encapsulation layer that encapsulates the bridge chip structure within the cavity.

6. The semiconductor package of claim 5, wherein the encapsulation layer comprises ceramic material, resin, or a combination thereof.

7. The semiconductor package of claim 1, wherein a depth of the cavity into the ceramic substrate is in a range of about 80 μm to about 200 μm.

8. The semiconductor package of claim 1, further comprising a capacitor structure at an interface between the ceramic substrate and the upper redistribution structure, wherein the capacitor structure is between a first one of the plurality of semiconductor chips and the ceramic substrate.

9. The semiconductor package of claim 1, wherein the plurality of semiconductor chips comprise logic semiconductor chips or memory semiconductor chips.

10. The semiconductor package of claim 1, wherein the bridge chip structure further comprises one or more of a capacitor, an inductor, and a switch.

11. A semiconductor package comprising:
a ceramic substrate having a cavity, the ceramic substrate comprising a plurality of first insulating layers, and a first circuit wiring layer between the plurality of first insulating layers;
a lower redistribution structure on a lower surface of the ceramic substrate, the lower redistribution structure comprising a plurality of second insulating layers and a second circuit wiring layer between the plurality of second insulating layers and electrically connected to the first circuit wiring layer;
an upper redistribution structure on an upper surface of the ceramic substrate, the upper redistribution structure comprising a plurality of third insulating layers and a third circuit wiring layer between the plurality of third insulating layers and electrically connected to the first circuit wiring layer;
a plurality of semiconductor chips arranged in a first direction on the upper redistribution structure;
a bridge chip structure in the cavity of the ceramic substrate and comprising a bridge chip electrically connecting the plurality of semiconductor chips to each other; and
an encapsulation layer encapsulating the bridge chip structure within the cavity, wherein the encapsulation layer comprises ceramic material, resin, or a combination thereof.

12. The semiconductor package of claim 11, wherein a depth of the cavity into the ceramic substrate is in a range of about 80 μm to about 200 μm.

13. The semiconductor package of claim 11,
further comprising a capacitor structure at an interface between the ceramic substrate and the upper redistribution structure,
wherein the capacitor structure comprises a lower electrode layer on the upper surface of the ceramic substrate, a dielectric layer on an upper surface of the lower electrode layer, and an upper electrode layer on an upper surface of the dielectric layer.

14. The semiconductor package of claim 13, wherein the lower electrode layer is connected to the first circuit wiring layer, and the upper electrode layer is connected to the third circuit wiring layer.

15. The semiconductor package of claim 13, wherein the lower electrode layer comprises the same material as the first circuit wiring layer, and the upper electrode layer comprises the same material as the third circuit wiring layer.

16. The semiconductor package of claim 15, wherein the lower electrode layer comprises silver or tungsten, and the upper electrode layer comprises at least one of copper, nickel, gold, platinum, titanium, chromium, or alloys thereof.

17. The semiconductor package of claim 11, wherein an upper surface of the encapsulation layer and the top surface of the ceramic substrate are co-planar.

18. A semiconductor package comprising:
a ceramic substrate having a cavity, the ceramic substrate comprising a plurality of first insulating layers, and a first circuit wiring layer between the plurality of first insulating layers;
a lower redistribution structure on a lower surface of the ceramic substrate, the lower redistribution structure comprising a plurality of second insulating layers and a second circuit wiring layer between the plurality of second insulating layers and electrically connected to the first circuit wiring layer;
an upper redistribution structure on an upper surface of the ceramic substrate, the upper redistribution structure comprising a plurality of third insulating layers and a third circuit wiring layer between the plurality of third insulating layers and electrically connected to the first circuit wiring layer;
a plurality of semiconductor chips arranged in a first direction on the upper redistribution structure and comprising a logic semiconductor chip or a high bandwidth memory (HBM) semiconductor chip;
a bridge chip structure in the cavity of the ceramic substrate and comprising a bridge chip electrically connecting the plurality of semiconductor chips to each other;
an encapsulation layer encapsulating the bridge chip structure within the cavity of the ceramic substrate, wherein the encapsulation layer comprises ceramic material, resin, or a combination thereof; and
a capacitor structure at an interface between the ceramic substrate and the upper redistribution structure, the capacitor structure comprising a lower electrode layer on the upper surface of the ceramic substrate, a dielectric layer on an upper surface of the lower electrode layer, and an upper electrode layer on an upper surface of the dielectric layer.

19. The semiconductor package of claim 18, wherein the lower electrode layer is connected to the first circuit wiring layer, and the upper electrode layer is connected to the third circuit wiring layer.

20. The semiconductor package of claim 18, wherein a vertical depth of the cavity into the ceramic substrate is in a range of about 80 μm to about 200 μm.
